(19) United States
(12) Patent Application Publication
(10) Pub. No.: US 2026/0189240 A1
(43) Pub. Date: Jul. 2, 2026

(54) A/D CONVERSION DEVICE AND BATTERY MONITORING INTEGRATED CIRCUIT DEVICE

(71) Applicant: DENSO CORPORATION, Kariya-city (JP)

(72) Inventors: Shogo KAWAHARA, Kariya-city (JP); Tomohiro NEZUKA, Kariya-city (JP); Kunihiko NAKAMURA, Kariya-city (JP)

(21) Appl. No.: 19/547,017

(22) Filed: Feb. 23, 2026

Related U.S. Application Data
(63) Continuation of application No. PCT/JP2024/027907, filed on Aug. 5, 2024.

(30) Foreign Application Priority Data
Aug. 25, 2023 (JP) JP2023-137231

(51) Int. Cl. H03M 1/08; H03M 1/00

(52) U.S. Cl. CPC H03M 1/0854; H03M 1/002

(57) ABSTRACT

An analog-to-digital (A/D) conversion device comprises: an integrator to which an input signal and an output of a digital-to-analog converter (DAC) are input; a quantizer to which a reference potential is applied and to which the output of the integrator is input; the DAC that performs digital-to-analog conversion of the output of the quantizer; a control circuit that performs switching between two or more operation modes including a second-order ΔΣ mode and a cyclic mode; and a potential generation circuit that switches the reference potential to be applied to the quantizer depending on the two or more operation modes.

### CROSS REFERENCE TO RELATED APPLICATIONS

The present application is a continuation application of International Patent Application No. PCT/JP 2024/027907 filed on Aug. 5, 2024, which designated the U.S. and claims the benefit of priority from Japanese Patent Application No. 2023-137231 filed on Aug. 25, 2023. The entire disclosures of all of the above applications are incorporated herein by reference.

### TECHNICAL FIELD

The present disclosure relates to an A/D conversion device and a battery monitoring integrated circuit device.

### BACKGROUND

A technology for executing an AD conversion process using a hybrid mode, which combines a ΔΣ method and a cyclic method, has been proposed by the inventor. Further, an A/D conversion device has been known as a comparative example, and operates in at least two modes including: a ΔΣ mode of the ΔΣ method; a hybrid mode that combines the ΔΣ method and the cyclic method; and a cyclic mode of the cyclic method.

### SUMMARY

According to an aspect of the present disclosure, an analog-to-digital (A/D) conversion device comprises: an integrator to which an input signal and an output of a digital-to-analog converter (DAC) are input; a quantizer to which a reference potential is applied and to which the output of the integrator is input; the DAC that performs digital-to-analog conversion of the output of the quantizer; a control circuit that performs switching between two or more operation modes including a second-order ΔΣ mode and a cyclic mode; and a potential generation circuit that switches the reference potential to be applied to the quantizer depending on the two or more operation modes.

### BRIEF DESCRIPTION OF DRAWINGS

FIG. 1 is a block diagram of an electrical configuration of an A/D conversion device according to a first embodiment.

FIG. 2 is an electrical configuration block diagram of a battery monitoring integrated circuit device according to the first embodiment.

FIG. 3 is a block diagram of an electrical configuration of a specific example of the A/D conversion device according to the first embodiment.

FIG. 4 is a detailed circuit configuration diagram of a specific example of the A/D conversion device according to the first embodiment (basic switch state in ΔΣ mode).

FIG. 5 is a detailed circuit configuration diagram of a specific example of an A/D conversion device according to the first embodiment (basic switch states in cyclic mode and hybrid mode).

FIG. 6 is a first electrical configuration diagram showing a part of a DAC according to the first embodiment.

FIG. 7 is a second electrical configuration diagram showing a part of the DAC according to the first embodiment.

FIG. 8 is a third electrical configuration diagram showing a part of the DAC according to the first embodiment.

FIG. 9 is a fourth electrical configuration diagram showing a part of the DAC according to the first embodiment.

FIG. 10 is a diagram for illustrating signal transmission paths of the cyclic mode and hybrid mode according to the first embodiment.

FIG. 11 is an electrical configuration diagram of a telescopic amplifier according to a second embodiment.

FIG. 12 is an electrical configuration diagram of a potential generation circuit according to a third embodiment.

FIG. 13 is an electrical configuration diagram of a potential generation circuit according to a fourth embodiment.

FIG. 14 is an electrical configuration diagram of a switch according to the fourth embodiment.

### DETAILED DESCRIPTION

For example, in a case of having a low-speed, high-precision battery status detection function and a high-speed, low-precision failure diagnosis function like a battery monitoring integrated circuit, when two A/D conversion devices are installed to accommodate two different specifications, the circuit's installation area and the power consumption increase.

Furthermore, when a single A/D conversion device is installed so as to switch between multiple operation modes, a reference potential becomes fixed. Therefore, an integrator operation in the A/D conversion device becomes saturated and unstable, resulting in a deterioration in precision. Furthermore, when a quantizer and a reference voltage generation circuit are provided for each operation mode, the power consumption of the entire quantizer increases, and the circuit installation area increases.

An example of the present disclosure provides an A/D conversion device and a battery monitoring integrated circuit device in which a reference potential to be applied to a quantizer can be set for each operation mode.

According to an aspect of the present disclosure, an A/D conversion device comprises: an integrator to which an input signal and an output of a digital-to-analog converter (DAC) are input; a quantizer to which a reference potential is applied and to which the output of the integrator is input; the DAC that performs digital-to-analog conversion of an output of the quantizer; a control circuit that performs switching between two or more operation modes including a second-order ΔΣ mode and a cyclic mode; and a potential generation circuit that switches the reference potential to be applied to the quantizer depending on the two or more operation modes.

According to the aspect of the present disclosure, the reference potential applied by the potential generation circuit to the quantizer can be switched depending on two or more operation modes, and the reference potential to be applied to the quantizer can be set for each operation mode.

Hereinafter, several embodiments of an A/D conversion device will be described. In each of the embodiments described below, the same or similar reference numerals are used to designate the same or similar configurations, and a description thereof will be omitted as necessary.

### FIRST EMBODIMENT

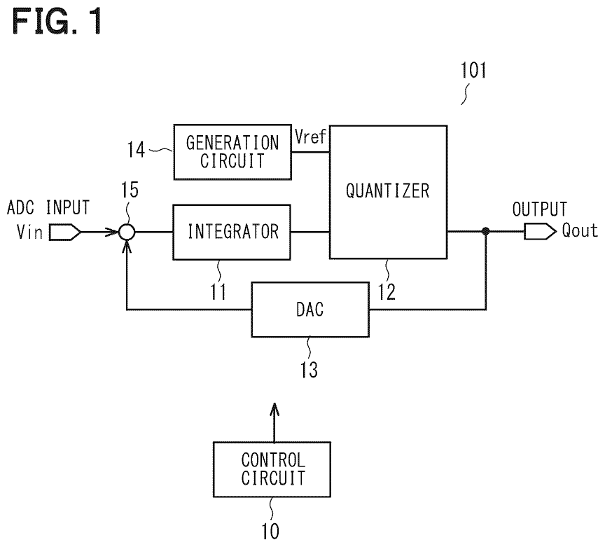

First, a configuration of an A/D conversion device 101 will be described with reference to FIG. 1. The A/D conversion device 101 shown in FIG. 1 performs AD conversion on an analog input signal Vin to obtain a high-resolution digital output, and is configured using a ΔΣ modulator including an integrator 11, a DAC 13, a quantizer 12, a potential generation circuit 14, an adder/subtractor 15, and a control circuit 10. In the drawings, the potential generation circuit 14 may be referred to as a generation circuit. A ΔΣ modulation is a type of pulse modulation method.

The integrator 11 receives the analog input signal Vin and the output of the DAC 13. Specifically, the integrator 11 receives and integrates the result of adding the output of the DAC 13 to the analog input signal Vin by the adder/subtractor 15 or subtracting the output of the DAC 13 from the analog input signal Vin.

The quantizer 12 includes, for example, a comparator, to which a reference potential Vref is applied from the potential generation circuit 14 and to which the output of the integrator 11 is input, and which outputs the result of comparing the output of the integrator 11 with the reference potential Vref.

The quantizer 12 is configured as a continuous-time amplifier type or a dynamic type. The potential generation circuit 14 includes a reference potential changeover switch 14a, and switches the reference potential Vref by the reference potential changeover switch 14a to output it to the quantizer 12 so that the output of the integrator 11 can be quantized by the quantizer 12. In the drawing, the reference potential changeover switch 14a may be referred to as a reference potential switch. The DAC 13 converts the output of the quantizer 12 and outputs it to the adder/subtractor 15. The output of the quantizer 12 is used as the output of the A/D conversion device 101.

The potential generation circuit 14 makes the reference potential Vref applied to the quantizer 12 switchable depending on the operation mode. For example, when the quantization bits of the quantizer 12 are a three level, the reference potential Vref is switched to a two level, which is one level less than the three level, for each operation mode, and the reference potential Vref is output to the quantizer 12. The quantizer 12 quantizes the input signal by comparing it with the two-level reference potential Vref.

The control circuit 10 switches between two or more operation modes including at least the second-order ΔΣ mode and a cyclic type mode. The ΔΣ mode refers to modes in which the AD conversion process is executed on the analog input signal Vin using the ΔΣ method. Among the modes, the second-order ΔΣ mode refers to a mode in which processing is performed by the ΔΣ method using the integrators 11 (first-order integrator 11a and second-order integrator 11b described later) connected in cascade in two stages. In the drawings, the first-order integrator 11a may be referred to as a first-order integrator, and the second-order integrator 11b may be referred to as a second-order integrator.

The cyclic type mode refers to a mode in which the AD conversion process is executed on the analog input signal Vin in the cyclic method. In addition, the operation modes that can be set by the control circuit 10 may include a hybrid mode in which the AD conversion process is executed by the ΔΣ method and then the AD conversion is executed on the analog residue by the cyclic method, and the control circuit 10 may be configured to switch between three or more operation modes.

The hybrid mode refers to a mode in which the high-order bits of the analog input signal Vin are AD-converted by the first-order ΔΣ method, and then the analog residual is AD-converted by the cyclic method. In hybrid mode, a first-order ΔΣ operation is performed at the start of AD conversion of the analog input signal Vin. A cyclic operation is performed by switching the on-off state of the switch during the AD conversion. The AD conversion result of the first-order ΔΣ operation and the AD conversion result of the cyclic operation are combined and output as the AD conversion result in the hybrid mode.

The first-order ΔΣ mode indicates a mode in which processing is performed by the first-order ΔΣ type operation using the integrator 11 configured in a single stage. The control circuit 10 switches between these operation modes and performs control in accordance with the operation mode.

When the control circuit 10 operates the A/D conversion device 101 in the ΔΣ mode, it switches the switch SW to connect a digital filter 16 to the downstream of the A/D conversion device 101. Thereby, the output of the digital filter 16 is set to the output data. When the control circuit 10 operates the A/D conversion device 101 in the cyclic mode or the hybrid mode, the output of the A/D conversion device 101 is used as output data as is.

In addition, in the hybrid mode, the A/D conversion device 101 uses a circuit in which a shift register and a digital accumulation circuit are connected in a dependent manner (not shown) to combine and connect the AD conversion results of the first-order ΔΣ operation and the AD conversion results of the cyclic operation. In the hybrid mode, the A/D conversion device 101 combines the AD conversion result of the first-order ΔΣ operation as the high-order bits and the AD conversion result of the cyclic operation as the low-order bits.

### (Method of Applying A/D Conversion Device)

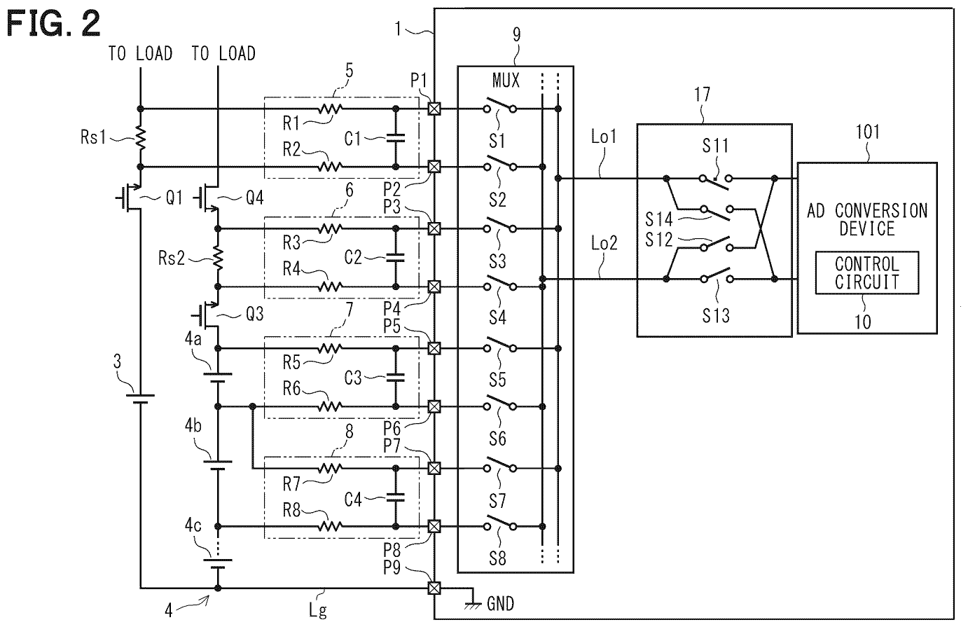

Next, a method for applying the A/D conversion device 101 shown in FIG. 1 will be described. As shown in FIG. 2, the A/D conversion device 101 can be incorporated into a battery monitoring integrated circuit device 1. The battery monitoring integrated circuit device 1 monitors a battery 3, an assembled battery 4, and the like mounted on a vehicle, and is configured as, for example, an ASIC. The battery 3 is a lead battery that serves as an auxiliary battery, and its positive terminal is connected to a vehicle load (not shown) via a transistor Q1, a shunt resistor Rs1, and a transistor Q2. The negative terminal of the battery 3 is connected to a ground line Lg. The ground line Lg is connected to a ground GND of the battery monitoring integrated circuit device 1.

The assembled battery 4 is configured by connecting a plurality of battery cells 4a, 4b, . . . , 4c, which are secondary batteries such as lithium ion batteries, in series in multiple stages. The plurality of battery cells 4a, 4b, . . . , 4c have a common-mode voltage superimposed thereon. The common mode voltage becomes higher for the battery cells located on the upper side of the assembled battery 4, that is, the cells connected to the higher potential side. In FIG. 1 and other figures, two battery cells 4a to 4b of the plurality of battery cells 4a, 4b, . . . , 4c and their corresponding configurations are shown, and the bottom stage battery cell 4c is also shown.

The positive terminal of the battery cell 4a located at the top of the assembled battery 4, that is, the battery cell 4a located on the highest potential side, is connected to a vehicle load via a transistor Q3, a shunt resistor Rs2, and a transistor Q4. The negative terminal of the battery cell 4c located at the bottom of the assembled battery 4, that is, the battery cell 4c located on the lowest potential side, is connected to the ground line Lg.

The power supply path from the battery 3 to the vehicle load can be opened and closed by the transistor Q1. The power supply path of the battery cell 4a to the vehicle load can be opened and closed by transistors Q3 and Q4. The battery monitoring integrated circuit device 1 has functions such as a function of detecting the current flowing through the battery 3 using the shunt resistor Rs1, a function of detecting the current flowing through the assembled battery 4, i.e., the battery cells 4a to 4c, using the shunt resistor Rs2, and a function of detecting the voltages of the battery cells 4a and 4b.

The battery monitoring integrated circuit device 1 has terminals P1 and P2 corresponding to the respective terminals of the shunt resistor Rs1, and terminals P3 and P4 corresponding to the respective terminals of the shunt resistor Rs2. Each terminal of the shunt resistor Rs1 is connected to the terminals P1 and P2 via a filter 5 for removing noise. The filter 5 is an RC filter consisting of a resistor R1 connected between the high potential terminal of the shunt resistor Rs1 and the terminal P1, a resistor R2 connected between the low potential terminal of the shunt resistor Rs1 and the terminal P2, and a capacitor C1 connected between the terminals P1 and P2.

Each terminal of the shunt resistor Rs2 is connected to the terminals P3 and P4 via a filter 6. The filter 6 is an RC filter configured similarly to the filter 5, and includes resistors R3 and R4 and a capacitor C2. The battery monitoring integrated circuit device 1 includes terminals P5 and P6 corresponding to the respective terminals of the battery cell 4a, terminals P7 and P8 corresponding to the respective terminals of the battery cell 4b, and a terminal P9 for supplying ground potential (0V).

Each terminal of the battery cell 4a is connected to the terminals P5 and P6 via a filter 7. The filter 7 is an RC filter configured similarly to the filter 5 or the like, and includes resistors R5 and R6 and a capacitor C3. Each terminal of the battery cell 4b is connected to the terminals P7 and P8 via a filter 8. The filter 8 is an RC filter configured similarly to the filter 5 or the like, and includes resistors R7 and R8 and a capacitor C4. The negative terminal of the battery cell 4c, that is, the ground line Lg, is connected to the terminal P9.

The battery monitoring integrated circuit device 1 includes a multiplexer 9 and the A/D conversion device 101. The multiplexer 9 includes switches S1 to S8, one terminal of which is connected to terminals P1 to P8, respectively. The other terminal of the switches S1, S3, S5, and S7 are commonly connected to a first output line Lo1. The other terminal of the switches S2, S4, S6, and S8 are commonly connected to a second output line Lo2. The control circuit 10 switches the switches S1 to S8 of the multiplexer 9, and thereby the voltage of the battery cells 4a, 4b, . . . , 4c can be detected using the A/D conversion device 101, and further the current flowing through the battery 3 or the assembled battery 4 can be detected.

A chop switch 17 is provided between the output of the multiplexer 9 and the input of the A/D conversion device 101. The chop switch 17 is configured by combining switches S11 to S14 as shown in the figure. The control circuit 10 turns on the switches S11 and S13 and turns off the switches S12 and S14, so that the voltage of the output line can be input to the A/D conversion device 101 as is. The control circuit 10 can invert the voltage of the output line by turning off the switches S11 and S13 and turning on the switches S12 and S14, and input it to the A/D conversion device 101. Thereby, the polarity of the analog input signal Vin of the A/D conversion device 101 can be switched.

### Specific Configuration Example of A/D Conversion Device

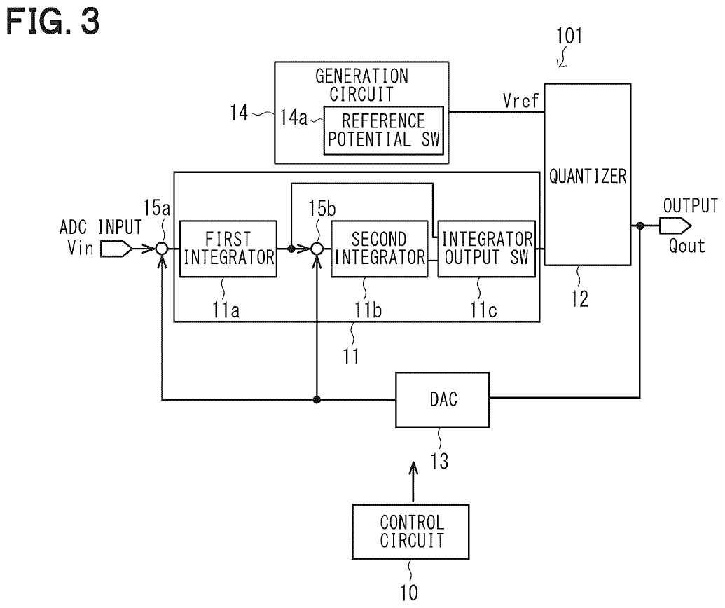

Hereinafter, a specific configuration example of the A/D conversion device 101 shown in FIG. 1 will be described with reference to FIGS. 3 to 10. As shown in FIG. 3, the integrator 11 includes the first-order integrator 11a, the second-order integrator 11b, and an integrator output changeover switch 11c. In the drawings, the integrator output changeover switch 11c may be referred to as an integrator output SW.

The first-order integrator 11a receives the analog input signal Vin and the output of the DAC 13 via an adder/subtractor 15a. The second-order integrator 11b receives the output of the first-order integrator 11a and the output of the DAC 13 via an adder-subtractor 15b. The integrator output changeover switch 11c is configured to selectively switch the input of the quantizer 12 to the output of the first-order integrator 11a or the output of the second-order integrator 11b. The control circuit 10 controls switching of the integrator output changeover switch 11c. Thereby, switching is performed to set the output of the first-order integrator 11a or the output of the second-order integrator 11b to the input to the quantizer 12. Thereby, it is possible to switch between the first-order ΔΣ mode of the first-order ΔΣ method and the second-order ΔΣ mode of the second-order ΔΣ method described above.

### Specific Configuration of Main Parts of A/D Conversion Device

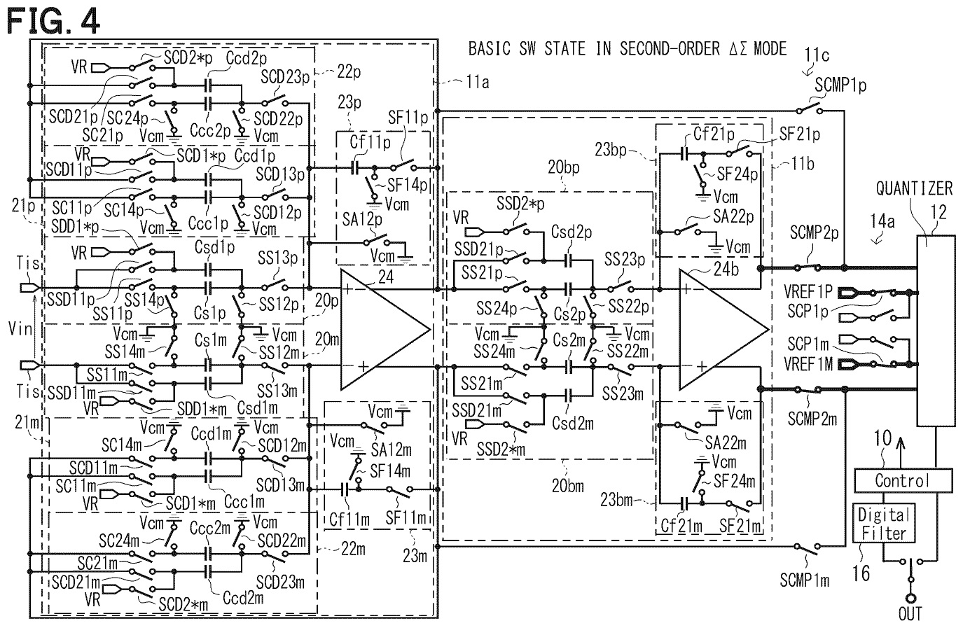

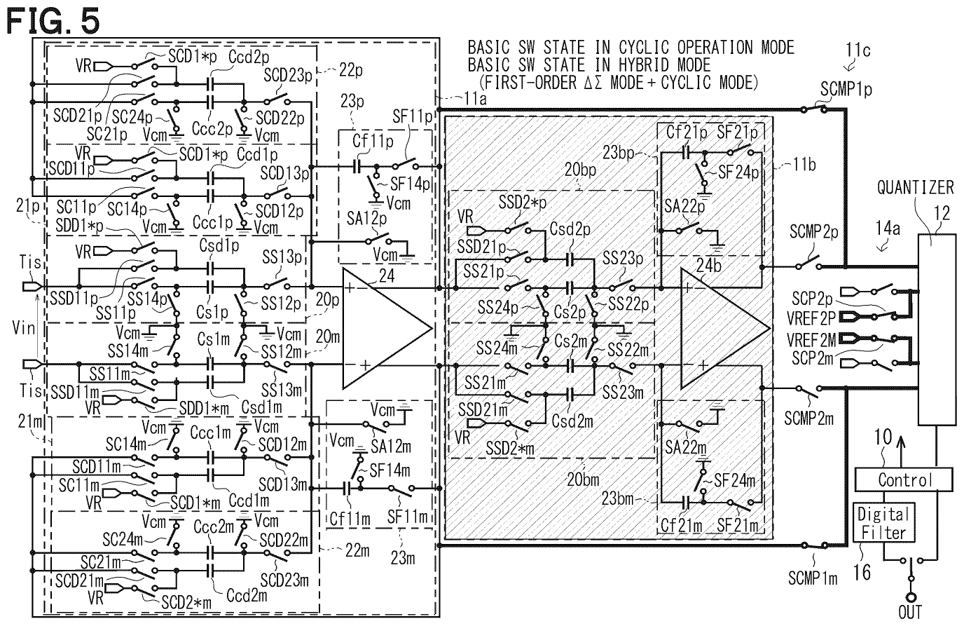

Hereinafter, the specific configuration of the main parts of the A/D conversion device 101 will be described with reference to FIGS. 4 and 5, and the operations in the second-order ΔΣ mode, cyclic mode, and hybrid mode will be described. FIG. 4 shows the basic switch state in the second-order ΔΣ mode, and FIG. 5 shows the basic switch states in the cyclic and hybrid modes.

The A/D conversion device 101 shown in FIGS. 4 and 5 includes the first-order integrator 11a, the second-order integrator 11b, the integrator output changeover switch 11c, the quantizer 12, the DAC 13, and the potential generation circuit 14. The analog input signal Vin is input to an input terminal Tis of the first-order integrator 11a.

The first-order integrator 11a includes capacitor switching circuits 20p to 23p and 20m to 23m, and a fully differential operational amplifier 24. The capacitor switching circuits 20p to 22p and 20m to 22m are connected symmetrically to the differential input terminals of the fully differential operational amplifier 24, respectively. In addition, the capacitor switching circuit 23p is connected between the non-inversion input terminal and the inversion output terminal of the fully differential operational amplifier 24, and the capacitor switching circuit 23m is connected between the inversion input terminal and the non-inversion output terminal.

The differential input terminals of the operational amplifier 24 are connected to the common output nodes of the capacitor switching circuits 20p to 22p and 20m to 22m, respectively. The differential output of the operational amplifier 24 is input to the input node of the second-order integrator 11b. In addition, in FIGS. 4 and 5, the components on each side of the differential configuration are denoted by reference numerals with the subscripts “p” and “m,” respectively. Since the configuration is symmetrical, in the following description, only the configuration on the side with the subscript p will be described, and the description of the configuration on the side with the subscript m will be omitted.

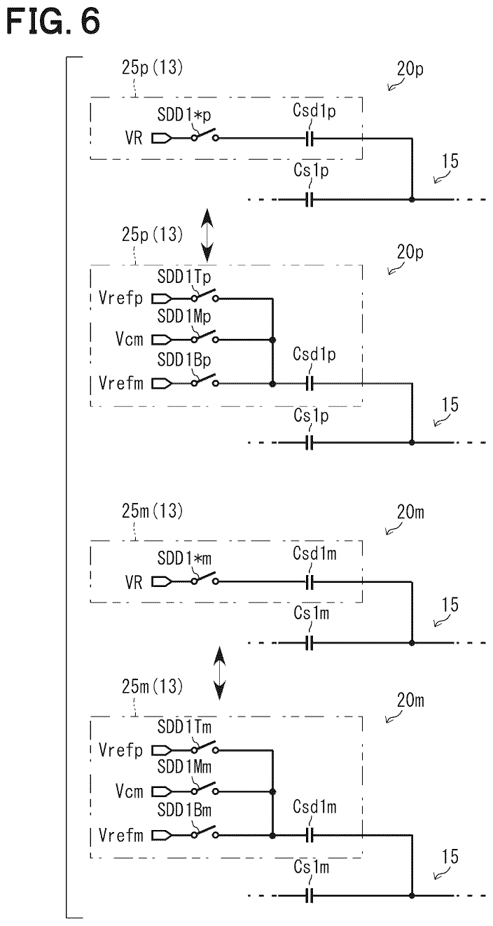

The capacitor switching circuit 20p includes a capacitor Cs1p, switches SS11p to SS14p, SSD11p, and a D/A converter 25p shown in FIG. 6. The capacitor Cs1 is used as a sampling capacitance for sampling the analog input signal Vin input from the input terminal Tis. The capacitor Cs1p charges and discharges electric charge in response to switching by the control circuit 10 between the on-state and off-state of the switches SS11p to SS14p. One terminal of the capacitor Cs1p is connected to the input terminal Tis via the switch SS11p, and is also connected to the common potential Vcm via the switch SS14p. The other terminal of the capacitor Cs1p is connected to the input node of the operational amplifier 24 via the switch SS13p, and is also connected to the common potential Vcm via the switch SS12p.

FIG. 6 shows a partial equivalent circuit of the capacitor switching circuit 20p shown in FIG. 4. As shown in FIGS. 4 and 6, the D/A converter 25p includes a switch SDD1*p and a capacitor Csd1p. The switch SDD1*p shown in FIG. 4 includes a plurality of switches SDD1Tp, SDD1Mp, and SDD1Bp as shown in FIG. 6.

The capacitor Csd1p is used as a DAC capacitance of the D/A converter 25p. As shown in FIG. 4, a switch SSD11p is connected between the input terminal Tis and the other terminal of the capacitor Csd1p. The switch SSD11p is a switch that is controlled when the capacitor Csd1p is used as a sampling capacitance, and is configured so that the on-off control is possible by the control circuit 10. The capacitor Csd1p may also function as a sampling capacitor for sampling the analog input signal Vin input from the input terminal Tis through the switch SSD11p.

The control circuit 10 selectively turns on the switches SDD1Tp, SDD1Mp, and SDD1Bp to apply one of the D/A converter reference potentials Vrefp, Vcm, and Vrefm to the other terminal of the capacitor Csd1p. The D/A converter reference potentials Vrefp, Vcm, and Vrefm correspond to analog voltages obtained by D/A converting the quantized output of the quantizer 12, and have a relationship of, for example, Vrefp>Vcm>Vrefm. The Vcm is a common potential. Hereinafter, the D/A converter output selected from the D/A converter reference potentials Vrefp, Vcm, and Vrefm will be referred to as VR. The D/A converter reference potentials Vrefp, Vcm, and Vrefm are voltages that depend on whether the input signal is larger or smaller than the reference potential Vref of the potential generation circuit 14, as determined by the quantizer 12.

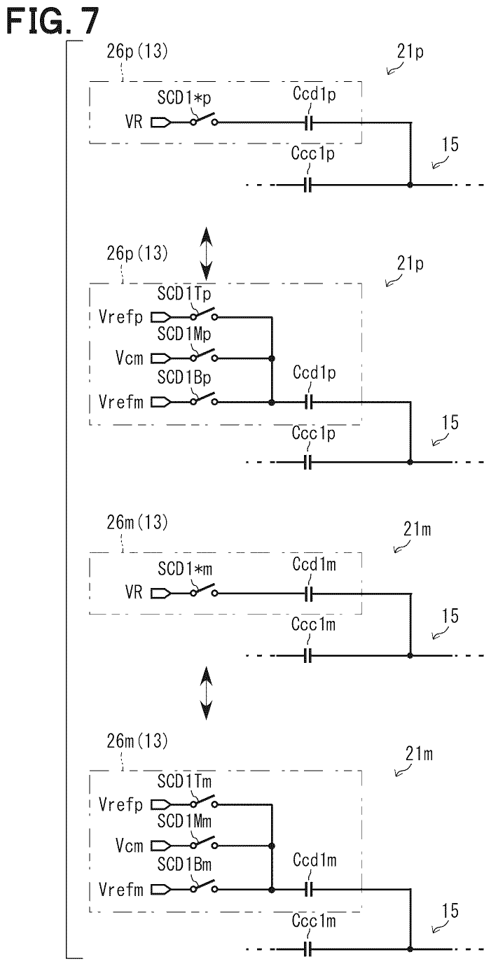

The capacitor switching circuit 21p shown in FIG. 4 includes a capacitor Ccc1p, switches SC11p, SC14p, SCD11p to SCD13p, and a D/A converter 26p shown in FIG. 7. The capacitor Ccc1p is configured to charge and discharge electric charge in response to switching by the control circuit 10 between the on-state and the off-state of the switches SC11p, SC14p, SCD12p, and SCD13p, respectively. One terminal of the capacitor Ccc1p is connected to the input node of the operational amplifier 24 via the switch SCD13p, and is also connected to the node of the common potential Vcm via the switch SCD12p. The other terminal of the capacitor Ccc1p is connected to the output node of the first-order integrator 11a via the switch SC11p, and is also connected to the node of the common potential Vcm via the switch SC14p.

FIG. 7 shows a partial equivalent circuit of the capacitor switching circuit 21p shown in FIG. 4. As shown in FIGS. 4 and 7, the D/A converter 26p includes a switch SCD1*p and a capacitor Ccd1p. The capacitor Ccd1p is used as a DAC capacitance of the D/A converter 26p. The switch SCD1*p shown in FIG. 4 includes a plurality of switches SCD1Tp, SCD1Mp, and SCD1Bp, as shown in FIG. 7.

The D/A converter 26p includes the plurality of switches SCD1Tp, SCD1Mp, SCD1Bp and the capacitor Ccd1p. The control circuit 10 selectively turns on the switches SCD1Tp, SCD1Mp, and SCD1Bp to apply one of the D/A converter reference potentials Vrefp, Vcm, and Vrefm to the other terminal of the capacitor Ccd1p as D/A converter output VR. The switch SCD11p is connected between the output node of the first-order integrator 11a and the other terminal of the capacitor Ccd1p. The switches SC11p and SCD11p are used when sampling the voltage of the output node of the first-order integrator 11a to the capacitors Ccc1p and Ccd1p in the cyclic method, and are configured so that the on-off control is possible by the control circuit 10.

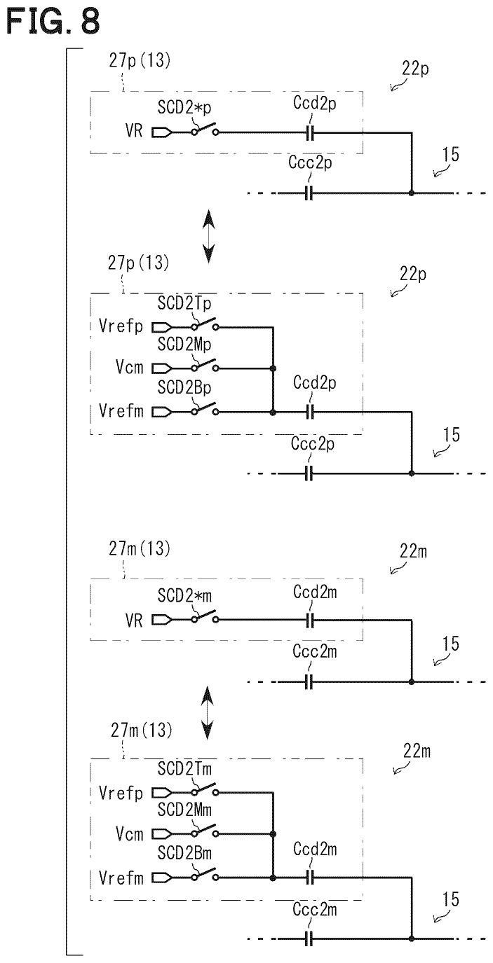

The capacitor switching circuit 22p shown in FIG. 4 includes a capacitor Ccc2p, switches SC21p, SC24p, SCD21p to SCD23p, and a D/A converter 27p shown in FIG. 8. The capacitor Ccc2p is configured to charge and discharge electric charge in response to switching by the control circuit 10 between the on-state and the off-state of each of the switches SC21p, SC24p, SCD22p, and SCD23p. One terminal of the capacitor Ccc2p is connected to the input node of the operational amplifier 24 via the switch SCD23p, and is also connected to the node of the common potential Vcm via the switch SCD22p. The other terminal of the capacitor Ccc2p is connected to the output node of the first-order integrator 11a via the switch SC21p, and is also connected to the node of the common potential Vcm via the switch SC24p.

FIG. 8 shows a partial equivalent circuit of the capacitor switching circuit 21p shown in FIG. 4. As shown in FIGS. 4 and 8, the D/A converter 27p includes a switch SCD2*p and a capacitor Ccd2p. The capacitor Ccd2p is used as a DAC capacitance of the D/A converter 27p. The switch SCD2*p shown in FIG. 4 includes a plurality of switches SCD2Tp, SCD2Mp, and SCD2Bp as shown in FIG. 8.

The D/A converter 27p includes a plurality of switches SCD2Tp, SCD2Mp, SCD2Bp and the capacitor Ccd2p. The control circuit 10 selectively turns on the switches SCD2Tp, SCD2Mp, and SCD2Bp to apply one of the D/A converter reference potentials Vrefp, Vcm, and Vrefm to the other terminal of the capacitor Ccd2p as the D/A converter output VR. A switch SCD21p is connected between the output node of the first-order integrator 11a and the other terminal of the capacitor Ccd2p. The switches SC21p and SCD21p are switches used when sampling the voltage of the output node of the first-order integrator 11a to the capacitors Ccc2p and Ccd2p by the cyclic method, and are configured so that they can be turned on and off by the control of the control circuit 10.

The capacitor switching circuit 23p shown in FIG. 4 includes switches SF11p, SF14p, SA12p, and a capacitor Cf11. The capacitor Cf11 is configured as a feedback capacitor between the input node of the operational amplifier 24 and the output node of the first-order integrator 11a. One terminal of the capacitor Cf11 is connected to the input node of the operational amplifier 24 and is also connected to the node of the common potential Vcm via the switch SA12p. The other terminal of the capacitor Cf11 is connected to the output node of the first-order integrator 11a via the switch SF11p, and is also connected to the node of the common potential Vcm via the switch SF14. As described above, the description of the wiring on the side with the subscript m will be omitted.

In a case where the switches in the capacitor switching circuits 20p to 23p and 20m to 23m are listed, the first-order integrator 11a includes switches SS11p to SS14p, SS11m to SS14m, SC11p, SC14p, SC11m, SC14m, SCD11p to SCD13p, SCD11m to SCD13m, SC21p, SC24p, SCD21p to SCD23p, SCD21m to SCD23m, SDD1*p, SCD1*p, SCD2*p, SF11p, SA12p, SF14p, SF11m, SA12m, and SF14m.

The input capacitors Cs1p, Csd1p, Cs1m, and Csd1m, and the capacitors Csd1p, Ccd1p, Ccd2p, Csd1m, Ccd1m, and Ccd2m of D/A converters 25p to 27p and 25m to 27m that configure the DAC 13, are configured to have the same capacitance value.

The control circuit 10 switches the on-off state of the switches SS11p to SS14p, SS11m to SS14m, SC11p, SC14p, SC11m, SC14m, SCD11p to SCD13p, SCD11m to SCD13m, SC21p, SC24p, SCD21p to SCD23p, SCD21m to SCD23m, SDD1*p, SCD1*p, SCD2*p, SF11p, SA12p, SF14p, SF11m, SA12m, and SF14m. Thereby, it is possible to switch the gain of a switched capacitor amplifier which combines these switches SS11p to SS14p, SS11m to SS14m, SC11p, SC14p, SC11m, SC14m, SCD11p to SCD13p, SCD11m to SCD13m, SC21p, SC24p, SCD21p to SCD23p, SCD21m to SCD23m, SDD1*p, SCD1*p, SCD2*p, SF11p, SA12p, SF14p, SF11m, SA12m, SF14m and capacitors Cs1p, Csd1p, Cs1m, Csd1m, Csd1p, Ccd1p, Ccd2p, Csd1m, Ccd1m, Ccd2m, Cf11p, Cf11m.

The capacitors Cs1p, Csd1p, Cs1m, and Csd1m, and the capacitors Csd1p, Ccd1p, Ccd2p, Csd1m, Ccd1m, and Ccd2m may be configured by combining unit capacitors of unit capacitance, each having the same area, in an array. Thereby, it is possible to prevent mismatches in the capacitance values of these capacitors as much as possible. Furthermore, it is possible to reduce the gain error of the switched capacitor amplifier, make the input/output characteristics of the A/D conversion device 101 highly linear, and implement a low gain error. Moreover, it is possible to eliminate the extra capacitor, and reduce the size. Here, the capacitors Cs1p, Csd1p, Cs1m, and Csd1m that constitute the first-order integrator 11a, and the capacitors Csd1p, Ccd1p, Ccd2p, Csd1m, Ccd1m, and Ccd2m are described. However, capacitors (described later) that constitute the second-order integrator 11b may also be configured to have the same capacitance value. Conversely, the capacitors described above may be configured to have different capacitance values.

The second-order integrator 11b is connected in cascade to the rear of the first-order integrator 11a. The second-order integrator 11b includes capacitor switching circuits 20bp, 20bm, 23bp, and 23bm, and a fully differential operational amplifier 24b. Capacitor switching circuits 20bp and 20bm are symmetrically connected to the differential input terminals of the fully differential operational amplifier 24b.

In addition, the capacitor switching circuit 23bp is connected between the non-inversion input terminal and the inversion output terminal of the fully differential operational amplifier 24, and the capacitor switching circuit 23bm is connected between the inversion input terminal and the non-inversion output terminal. In the following description, as in the above, only the configuration on the side with the subscript p will be described, and the description of the configuration on the side with the subscript m will be omitted.

The capacitor switching circuit 20bp includes a capacitor Cs2p, switches SS21p to SS24p, and a D/A converter 25bp shown in FIG. 8. The capacitor Cs2p is used as a sampling capacitor for sampling the output voltage input from the output node of the first-order integrator 11a through the switch SS21p. The capacitor Cs2p charges and discharges electric charge in response to the control circuit 10 turning on or off each of the switches SS21p to SS24p. The differential input terminals of the operational amplifier 24 are connected to the output nodes of the capacitor switching circuits 20bp and 20bm.

One terminal of the capacitor Cs2p is connected to the output node of the first-order integrator 11a via the switch SS21p, and is also connected to the node of the common potential Vcm via the switch SS24p. The other terminal of the capacitor Cs2p is connected to the input node of the operational amplifier 24b via the switch SS23p, and is also connected to the node of the common potential Vcm via a switch SS22p.

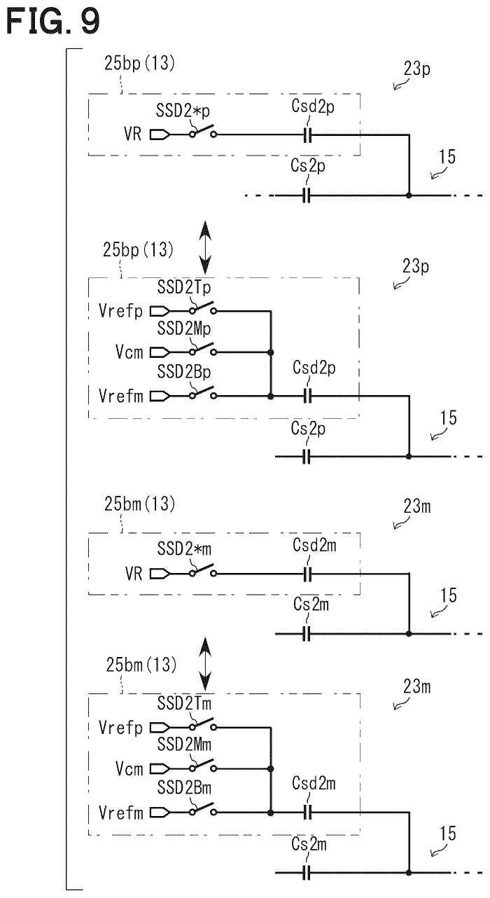

FIG. 9 shows a partial equivalent circuit of the capacitor switching circuit 20bp shown in FIG. 4. As shown in FIGS. 4 and 9, the D/A converter 25bp includes a switch SSD2*p and a capacitor Csd2p. The switch SSD2*p shown in FIG. 4 includes a plurality of switches SCD2Tp, SCD2Mp, and SCD2Bp, as shown in FIG. 9.

The D/A converter 25bp includes a plurality of switches SDD2Tp, SDD2Mp, SDD2Bp and the capacitor Csd2. The control circuit 10 selectively turns on the switches SDD2Tp, SDD2Mp, and SDD2Bp to apply one of the D/A converter reference potentials Vrefp, Vcm, and Vrefm as the D/A converter output VR to the other terminal of the capacitor Csd2.

The capacitor switching circuit 23bp includes switches SF21p, SF24p, SA21p, and a capacitor Cf21p. Capacitor Cf21p is configured as a feedback capacitor between the input and output nodes of operational amplifier 24b. One terminal of the capacitor Cf21p is connected to the output node of the operational amplifier 24b, and is also connected to the node of the common potential Vcm via a switch SA22p. The other terminal of the capacitor Cf21p is connected to the output node of the second-order integrator 11b via the switch SF21p, and is also connected to the node of the common potential Vcm via the switch SF24p. As described above, the description of the configuration on the side with the subscript m will be omitted.

### Integrator Output Changeover Switch and Reference Potential Switch

The integrator output changeover switch 11c shown in FIG. 3 includes switches SCMP1p, SCMP2p, SCMP1m, and SCMP2m shown in FIG. 4. As shown in FIG. 4, switches SCMP1p and SCMP1m are connected between the output node of the first-order integrator 11a and the input of the quantizer 12. In addition, switches SCMP2p and SCMP2m are connected between the output node of the second-order integrator 11b and the input node of the quantizer 12.

The control circuit 10 alternately switches between a state in which switches SCMP1p and SCMP1m are turned on and switches SCMP2p and SCMP2m are turned off, and a state in which switches SCMP1p and SCMP1m are turned off and switches SCMP2p and SCMP2m are turned on. Thereby, the output of the first-order integrator 11a or the output of the second-order integrator 11b is selectively input to the quantizer 12.

On the other hand, the potential generation circuit 14 shown in FIG. 3 generates the reference potentials VREF1P, VREF2P, VREF1M, and VREF2M shown in FIG. 4 or FIG. 5. The reference potential is selectively switched by the reference potential changeover switch 14a and output to the quantizer 12 as the reference potential Vref.

The reference potential changeover switch 14a of the potential generation circuit 14 includes switches SCP1p, SCP2p, SCP1m, and SCP2m, and outputs the plurality of reference potentials Vref to the quantizer 12. A specific configuration example of the potential generation circuit 14 will be described later in the third and fourth embodiments.

The control circuit 10 switches between a state in which switches SCP1p and SCP1m are turned on and switches SCP2p and SCP2m are turned off, and a state in which switches SCP1p and SCP1m are turned off and switches SCP2p and SCP2m are turned on. Thereby, the reference potential Vref suitable for the operation mode can be input to the quantizer 12.

FIG. 4 shows the basic states of the integrator output changeover switch 11c and the reference potential changeover switch 14a in the second-order ΔΣ mode. In the second-order ΔΣ mode, the control circuit 10 turns off the switches SCMP1p and SCMP1m and turns on the switches SCMP2p and SCMP2m, thereby selectively inputting the output of the second-order integrator 11b to the quantizer 12. Furthermore, the control circuit 10 switches on the switches SCP1p and SCP1m and switches off the switches SCP2p and SCP2m, thereby switching the reference potential Vref suitable for the second-order ΔΣ mode and inputting it to the quantizer 12.

Further, FIG. 5 shows the basic states of the integrator output changeover switch 11c and the reference potential changeover switch 14a in the cyclic mode and the hybrid mode. In the cyclic mode and the hybrid mode, the control circuit 10 selectively inputs the output of the second-order integrator 11b to the quantizer 12 by turning on the switches SCMP1p and SCMP1m and turning off the switches SCMP2p and SCMP2m. The control circuit 10 turns off the switches SCP1p and SCP1m and turns on the switches SCP2p and SCP2m to perform switching and inputting of the reference potential Vref suitable for the cyclic mode or hybrid mode to the quantizer 12.

In such a manner, it is desirable that the control circuit 10 switches the integrator output changeover switch 11c and the reference potential changeover switch 14a in synchronization with the switching of the AD conversion operation mode, i.e., the switching between the second-order ΔΣ mode, the cyclic mode, and the hybrid mode. Thereby, the quantizer 12 is supplied with the reference potential Vref suitable for each operation mode.

The quantizer 12 compares the integrator output with a reference potential Vref, generates a three-level (1.5-bit) quantized output, and feeds it back to the DAC 13. Which of the above-described D/A converter reference potentials Vrefp, Vcm, and Vrefm is output as the D/A converter output VR depends on the magnitude relationship between the input signal and the reference potential Vref of the potential generation circuit 14, as determined by the quantizer 12. Therefore, even when a stable operation range and saturation level of the integrator output differ for each operation mode, the potential generation circuit 14 can switch the reference potential Vref. Thereby, an appropriate reference is selected from the D/A converter reference potentials Vrefp, Vcm, and Vrefm and output as the D/A converter output VR. As the result, it is possible to control the integrator output to be within the stable operation range, and enable A/D conversion with high precision.

### (Description of Each Operation Mode)

Below, the operations of the first-order integrator 11a and the second-order integrator 11b in each operation mode of the second-order ΔΣ mode, the cyclic mode, and the hybrid mode will be briefly described. In the following description of the operation, the switches for the on-control by the control circuit 10 in each operation mode will be described, and a description of the switches for the off-control by the control circuit 10 will be omitted. Furthermore, since the configuration is differential and symmetrical as described above, in the following description, the subscripts “p, m” of the components that are symmetrical to the subscripts “p, m” will not be added.

### (1) Second-Order ΔΣ Mode

In the second-order ΔΣ mode, the A/D conversion device 101 performs a so-called oversampling type AD conversion process. At this time, the potential generation circuit 14 generates a reference potential Vref suited to the second-order ΔΣ mode based on the control by the control circuit 10 and outputs it to the quantizer 12 to adjust the output of the quantizer 12. The reference potential Vref that the potential generation circuit 14 outputs to the quantizer 12 in the second-order ΔΣ mode is set to be smaller than the reference potential Vref that is output in the cyclic mode and hybrid mode, which will be described later. In the second-order ΔΣ mode, the first-order integrator 11a and the second-order integrator 11b are used for operation, but the operational stability of the integrator 11 can be ensured. The quantizer 12 can perform quantization appropriately.

Both the first-order integrator 11a and the second-order integrator 11b simultaneously perform a reset operation, a ΔΣ sample operation, and a ΔΣ hold operation in parallel, and then repeatedly perform the ΔΣ sample operation and the ΔΣ hold operation. At this time, the A/D conversion device 101 performs AD conversion processing by oversampling these operations a predetermined number of times. The quantizer 12 continues to perform quantization and outputting, and the output of the quantizer 12 is low-pass filtered by the digital filter 16 to produce output data.

### (Reset Operation)

First, the control circuit 10 turns on switches SS14, SS12, SDD1M, SC14, SCD12, SCD1M, SC24, SCD22, SCD2M, SA12, and SF14 to discharge the accumulated charges in capacitors Cs1, Csd1, Ccc1, Ccd1, Ccc2, Ccd2, and Cf11 to the node at common potential Vcm. Thereby, the first-order integrator 11a is reset. The control circuit 10 turns on switches SS22, SS24, SDD2M, SA22, and SF24 to discharge the charges accumulated in the capacitors Cs2, Csd2, and Cf21 to the node at the common potential Vcm. Thereby, the second-order integrator 11b is reset. The control circuit 10 resets the digital filter 16 before switching to the ΔΣ mode.

During the ΔΣ mode described below, the control circuit 10 continues to keep the on-state of the switches SCD12, SCD1M, SC14, SCD22, SCD2M, and SC24 of the first-order integrator 11a. Therefore, the voltage across each of the capacitors Ccc1, Ccd1, Ccc2, and Ccd2 is maintained at zero.

### (ΔΣ Sampling Operation in ΔΣ Mode)

The control circuit 10 turns on the switches SSD11, SS12, SS14, SCD1M, SCD12, SC14, SCD2M, SCD22, SC24, and SF11 of the first-order integrator 11a. At this time, the control circuit 10 turns on the switches SSD11, SS12, and SS14 of the first-order integrator 11a, causing the capacitor Csd1 to sample the analog input signal Vin. Furthermore, when the control circuit 10 turns on the switch SF11, the capacitor Cf11 is connected between the inversion input terminal and the output terminal of the operational amplifier 24.

Furthermore, the control circuit 10 turns on the switches SS21, SS22, and SSD2M of the second-order integrator 11b. Thereby, the output of the first-order integrator 11a is input to the other terminal of the capacitor Cs1. At this time, the capacitor Cs2 samples the output of the first-order integrator 11a.

At the same time, for causing the control circuit 10 to turn on the switch SF21, the capacitor Cf21 is connected between the input node and the output node of the operational amplifier 24b. Thereby, the second-order integrator 11b can output a voltage according to the charge accumulated in the capacitor Cf21. As described above, the control circuit 10 turns on the switch SCMP2. Therefore, the output of the second-order integrator 11b is connected to the quantizer 12. Thereby, the quantizer 12 outputs a quantizer output Qout (Quantizer out) obtained by quantizing the output of the second-order integrator 11b. The control circuit 10 selects one of the D/A converter reference potentials Vrefp, Vcm, and Vrefm to be output for D/A conversion based on the quantizer output Qout.

### (ΔΣ Hold Operation in ΔΣ Mode)

Next, the control circuit 10 controls the switches SS14, SS13, SCD1M, SCD12, SC14, SCD2M, SCD22, SC24, and SF11 of the first-order integrator 11a to turn on them. At this time, the control circuit 10 turns on the switch SS13, so that one end of the capacitors Cs1 and Csd1 can be connected to the input terminal of the operational amplifier 24. Furthermore, the control circuit 10 turns on the switch SF11. Therefore, the capacitor Cf11 can be connected to the input/output terminal of the operational amplifier 24.

Furthermore, the control circuit 10 turns on a switch (here, SDD1T) that constitutes the D/A converter to output the D/A converter output VR. During ΔΣ sample operation described above, charge is accumulated in capacitor Csd1. However, during ΔΣ hold operation, charge according to the D/A converter output VR is subtracted from the accumulated charge in capacitor Csd1, and the residual charge fed back is moved to capacitor Cf11. Thereby, the residual charge is accumulated in the capacitor Cf11, and the first-order integrator 11a outputs an integrated voltage according to the accumulated charge in the capacitor Cf11 from its output node.

On the other hand, the control circuit 10 turns on the switches SS23, SS24, and SF21 in the second-order integrator 11b and the switch (here, SDD2T) of the D/A converter 25b to output the D/A converter output VR. During the (ΔΣ sample operation) described above, charge is accumulated in capacitor Cs2. However, during the (ΔΣ hold operation), charge according to the D/A converter output VR is subtracted from the accumulated charge in capacitor Cs2, and the residual charge fed back is moved to capacitor Cf21. Thereby, the residual charge is accumulated in the capacitor Cf21, and the operational amplifier 24b outputs, to the output node, an integrated voltage by the second order integrator 11b according to the accumulated charge in the capacitor Cf21.

The first-order integrator 11a and the second-order integrator 11b simultaneously and alternately repeat the above-described operations of (ΔΣ sample operation) and (ΔΣ hold operation) a predetermined number of times. In this ΔΣ mode, the first-order integrator 11a and the second-order integrator 11b are in the same operation state at the same timing. The control circuit 10 of the A/D conversion device 101 oversamples these operations while the quantizer 12 continues to output values. The output values of the quantizer 12 are low-pass filtered by the digital filter 16 to produce output data.

In such a manner, in the ΔΣ mode, the operational amplifier 24 of the first-order integrator 11a and the operational amplifier 24b of the second-order integrator 11b are used. While the output of the second-order integrator 11b is quantized by the quantizer 12, the AD conversion process is executed using the ΔΣ method. In the ΔΣ mode, the effect of noise shaping is enhanced due to the quadratic modulation characteristics. It is possible to perform highly accurate A/D conversion.

### (2) Hybrid Mode

In the hybrid mode, the A/D conversion device 101 uses the first-order integrator 11a without using the operational amplifier 24b of the second-order integrator 11b to execute the AD conversion process on the analog input signal Vin using the ΔΣ method, and then executes the AD conversion process on the residual using the cyclic method. At this time, the potential generation circuit 14 generates the reference potential Vref suited to the hybrid mode under the control of the control circuit 10 and outputs it to the quantizer 12 to adjust the quantized output of the quantizer 12.

In the hybrid mode, the A/D conversion device 101 may execute an amplification process by connecting a capacitor and a switch (neither shown) in parallel with the capacitor Cf11, after executing the A/D conversion process using the ΔΣ method and before executing the A/D conversion process using the cyclic method. In the following description, a form in which no amplification process is executed will be described.

### (Reset Operation in Hybrid Mode)

First, the control circuit 10 simultaneously resets the first-order integrator 11a and the second-order integrator 11b. The processing operation at this time is the same as the reset operation in the ΔΣ mode, and therefore a description thereof will be omitted. Thereafter, the A/D conversion device 101 executes the oversampling process by alternately repeating the ΔΣ sampling operation and the ΔΣ holding operation of the ΔΣ method a predetermined number of times (for example, several tens of times) using only the first-order integrator 11a.

### (ΔΣ Sampling Operation in Hybrid Mode)

The control circuit 10 turns on the switches SDD1M, SS11, and SS12 of the first-order integrator 11a to cause the capacitor Cs1 to sample the analog input signal Vin. At the same time, the control circuit 10 turns on the switch SF11, so that the capacitor Cf11 is connected between the input terminal and the output terminal of the operational amplifier 24.

Further, the control circuit 10 also connects the output of the first-order integrator 11a to the quantizer 12 by turning on the switch SCMP1. As a result, the quantizer 12 quantizes the output of the first-order integrator 11a and outputs the quantized result to the control circuit 10 in the digitalized manner. The control circuit 10 then selects the D/A converter output VR to be used in the subsequent ΔΣ hold operation.

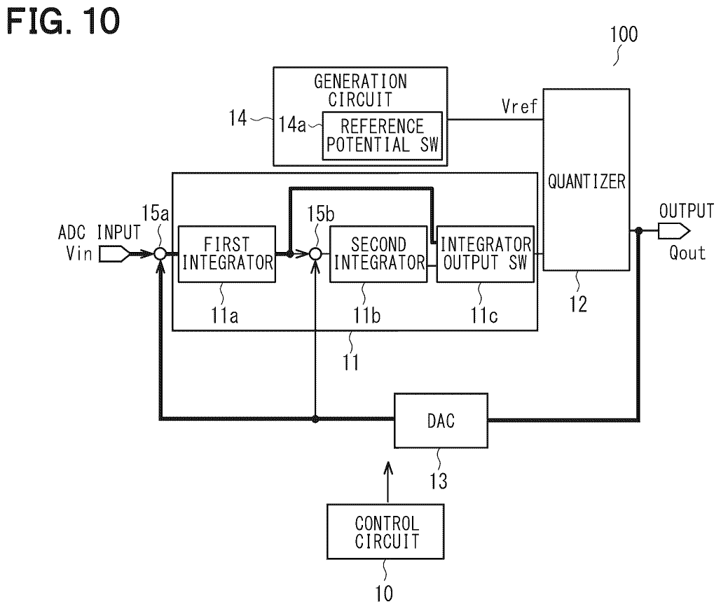

On the other hand, the control circuit 10 turns on the switches SS22, SS24, SDD2M, and SF21 of the second-order integrator 11b. Thereby, the potentials across the capacitors Cs2 and Csd2 are set to the common potential Vcm, and the operational amplifier 24 becomes into a feedback state. Therefore, the second-order integrator 11b can become into an inactive state, as shown by a bold line in FIG. 10.

### (ΔΣ Hold Operation in Hybrid Mode)

The control circuit 10 outputs the D/A converter output VR by turning on the switches SS14 and SS13 of the first-order integrator 11a and the switch (here, SDD1T) of the D/A converter 25, and connects one end of the capacitors Cs1 and Csd1 to the inversion input terminal of the operational amplifier 24. During the ΔΣ sample operation described above, charge is accumulated in capacitor Cs1. However, during the ΔΣ hold operation, charge according to the D/A converter output VR is subtracted from the accumulated charge in capacitor Cs1, and the residual charge that is fed back moves to capacitor Cf11. Thereby, the residual charge is accumulated in the capacitor Cf11, and the operational amplifier 24 outputs, from the output node, an integrated voltage by the first-order integrator 11a according to the accumulated charge in the capacitor Cf11.

In such a manner, the A/D conversion device 101 executes the AD conversion process using the ΔΣ method by repeatedly executing operations of (ΔΣ sample operation in hybrid mode) and (ΔΣ hold operation in hybrid mode) a predetermined number of times.

(First Part of Cyclic Operation in Hybrid mode)

Thereafter, the A/D conversion device 101 executes the A/D conversion process using the cyclic method. The control circuit 10 turns on the switches SC24, SCD22, and SCD2M to charge and discharge the accumulated charges in the capacitors Ccc2 and Ccd2 to the common potential Vcm to reset them. Furthermore, the control circuit 10 connects the capacitor Cf11 between the input and output terminals of the operational amplifier 24 by turning on the switch SF11.

Furthermore, the control circuit 10 turns on the switches SC11, SCD11, and SCD12 to connect the output node of the first-order integrator 11a to one end of the capacitors Ccc1 and Ccd1, and samples the output voltage of the first-order integrator 11a onto the capacitors Ccc1 and Ccd1.

### (Second Part of Cyclic Operation Hybrid Mode)

Next, the control circuit 10 turns on switches SC14, SCD13, and a switch of the D/A converter 26 (here, SCD1T) to output the D/A converter output VR and connect one end of the capacitors Ccc1 and Ccd1 to the input node of the operational amplifier 24. In the first part of the cyclic operation described above, the output of the first-order integrator 11a is sampled onto the capacitors Ccc1 and Ccd1. However, in the second part of the cyclic operation, a charge according to the D/A converter output VR is subtracted from the accumulated charge of these capacitors Ccc1 and Ccd1, and the residual charge that is fed back is moved to the capacitor Cf11. Thereby, the remaining charge is accumulated in the capacitor Cf11.

At the same time, the control circuit 10 turns on the switches SC21, SCD21, and SCD22 to connect the output node of the first-order integrator 11a to one end of the capacitors Ccc2 and Ccd2, and samples the output of the first-order integrator 11a onto the capacitors Ccc2 and Ccd2. Thereby, the first-order integrator 11a can perform a cyclic sample operation using the capacitor switching circuit 22 while performing a cyclic hold operation using the capacitor switching circuit 21, and thus can perform the cyclic sample operation and the cyclic hold operation simultaneously.

### (Third Part of Cyclic Operation Hybrid Mode)

Next, the control circuit 10 turns on switches SC24, SCD23, and a switch of the D/A converter 27p (here, SCD2T) to output the D/A converter output VR and connects one end of the capacitors Ccc2 and Ccd2 to the inversion input terminal of the operational amplifier 24. In the second part of cyclic operation described above, the output voltage of the first-order integrator 11a is sampled to the capacitors Ccc2 and Ccd2. However, in the third part of cyclic operation, a charge according to the D/A converter output VR is subtracted from the accumulated charge in these capacitors Ccc2 and Ccd2, and the residual charge that is fed back is moved to the capacitor Cf11. Thereby, the remaining charge is accumulated in the capacitor Cf11.

At the same time, the control circuit 10 turns on the switches SC11, SCD11, and SCD12 to connect the output node of the first-order integrator 11a to one end of the capacitors Ccc1 and Ccd1, and samples the output of the first-order integrator 11a onto the capacitors Ccc1 and Ccd1. Thereby, the first-order integrator 11a can perform the cyclic sample operation using the capacitor switching circuit 21 while performing the cyclic hold operation using the capacitor switching circuit 22. The cyclic sample operation and the cyclic hold operation can be performed simultaneously.

Thereafter, the first-order integrator 11a repeats the second part and the third part of cyclic operations. Accordingly, the control circuit 10 adds, as successive lower bits, the quantized values obtained through the A/D conversion process using the cyclic method with respect to the value of the upper bits generated by the ΔΣ method, by using a shift register or a data accumulation circuit to shift the digit positions sequentially. The result of this addition is used as output data. In this way, the final A/D conversion result is obtained.

### (3) Cyclic Mode

In the cyclic mode, the A/D conversion device 101 executes the AD conversion process of the analog input signal Vin by the cyclic method by using the configuration of the first-order integrator 11a without using the second-order integrator 11b. To reduce power consumption, the operating current of the unused second-order integrator 11b is cut in this cyclic mode. At this time, the control circuit 10 may cut off the power supply voltage VDD of the operational amplifier 24b that constitutes the second-order integrator 11b for cutting off the operating current of the second-order integrator 11b. Thereby, it is possible to reduce current consumption. Further, the potential generation circuit 14 adjusts the output of the quantizer 12 by generating the reference potential Vref suited to the cyclic mode under the control of the control circuit 10 and outputting it to the quantizer 12.

### (Reset Operation in Cycling Mode)

First, the control circuit 10 simultaneously resets the first-order integrator 11a and the second-order integrator 11b. The processing operation at this time is the same as the reset operation in the ΔΣ mode, and therefore a description thereof will be omitted. Thereafter, the A/D conversion device 101 alternately repeats the cyclic sampling operation and the cyclic holding operation of the cyclic method a predetermined number of times (for example, a dozen or so times) using only the first-order integrator 11a.

### (Cyclic Sample Operation in Cyclic Mode)

The control circuit 10 turns on the switches SDD1M, SS11, and SS12 of the first-order integrator 11a to cause the capacitor Cs1 to sample the analog input signal Vin. At the same time, the control circuit 10 turns on the switch SF11, so that the capacitor Cf11 is connected between the input and output terminals of the operational amplifier 24. Furthermore, the control circuit 10 turns on the switch SCMP1 to input the output of the first-order integrator 11a to the quantizer 12.

Next, the control circuit 10 turns on the switches SS13 and SS14 to transfer the charge accumulated in the capacitor Cs1 to the capacitor Cf11. At the same time, the control circuit 10 turns on the switches SC11, SCD11, and SCD12 to connect the output node of the first-order integrator 11a to one end of the capacitors Ccc1 and Ccd1, and samples the output of the first-order integrator 11a onto the capacitors Ccc1 and Ccd1. Thereby, the first-order integrator 11a can perform cyclic sampling using the capacitor switching circuit 21.

Thereafter, the first-order integrator 11a repeats the same operations as (second part of cyclic operation in hybrid mode) and (third part of cyclic operation in hybrid mode). This is the same as above, so the description will be omitted. Thereby, it is possible to execute the AD conversion process by the cyclic method using the first-order integrator 11a without using the second-order integrator 11b.

### SUMMARY OF PRESENT EMBODIMENT

According to the present embodiment, the A/D conversion device 101 can be configured so that the quantizer 12 and the potential generation circuit 14 are shared among the second-order ΔΣ mode, the cyclic mode, and the hybrid mode. Thereby, it is possible to reduce the size. In a case of installation with the same configuration area as before, it is possible to increase the power used for other circuits, and increase the configuration area. It is possible to implement higher speed and higher precision. Furthermore, by using the integrator 11 described above, it is possible to implement the switching configuration between the second-order ΔΣ mode and other operation modes.

The A/D conversion device 101 executes the AD conversion process using the first-order integrator 11a and the second-order integrator 11b in the second-order ΔΣ mode, and executes the AD conversion process using only the first-order integrator 11a in the hybrid mode and cyclic mode. As a result, in modes other than the second-order ΔΣ mode, in other words, in the hybrid mode and cyclic mode, the A/D conversion device 101 does not need to operate the second-order integrator 11b.

The A/D conversion device 101 can be implemented with low power consumption because the power consumption of the second-order integrator 11b can be reduced in the cyclic mode and the hybrid mode. In the hybrid mode and cyclic mode, the second-order integrator 11b is not used. Therefore, the operational amplifier 24b of the second-order integrator 11b can be an operational amplifier with a lower gain error than the operational amplifier 24 of the first-order integrator 11a.

In the present embodiment, the A/D conversion device 101 uses the capacitor Csd1 as the sampling capacitance in the ΔΣ mode, and uses the capacitor Cs1 as the sampling capacitance in the hybrid mode and cyclic mode. For example, when the capacitance values of capacitors Cs1 and Csd1 are set to be identical to each other, the input sampling capacitance can be made to provide the same gain between the ΔΣ mode and the other modes. Conversely, for example, when the capacitance values of capacitors Cs1 and Csd1 are set to be different from each other, the input sampling capacitance can be used to switch the gain between the ΔΣ mode and the other modes.

Generally, when the ΔΣ mode is adopted, the A/D conversion precision is higher than that of the cyclic mode due to the effect of oversampling. However, when the ΔΣ mode is adopted, the A/D conversion precision can be maintained even when the capacitance value of the sampling capacitance by capacitor Csd1 is reduced. In this case, the configuration area required for the sampling capacitance of the capacitor Csd1 can be minimized. Conversely, by setting the capacitance value of the sampling capacitance of the capacitor Csd1 to a large value, it is possible to further improve the A/D conversion precision in the ΔΣ mode.

The integrator output changeover switch 11c is configured to selectively switch the input to the quantizer 12 to the output of the first-order integrator 11a or the output of the second-order integrator 11b. Therefore, in the layout of the battery monitoring integrated circuit device 1, for example, when the first-order integrator 11a and the second-order integrator 11b are arranged side by side along a predetermined direction (for instance, the horizontal direction) on the surface of the semiconductor substrate, it is preferable to place the quantizer 12 in the intersecting direction (upward or downward). With this configuration, it is possible to shorten a wiring connecting the first-order integrator 11a, shown by the thick line in FIG. 10, to the quantizer 12 via the integrator output changeover switch 11c. As a result, it is possible to reduce interference between circuits, and make circuit operation faster.

The reference potential Vref that the potential generation circuit 14 outputs to the quantizer 12 in the second-order ΔΣ mode is set to be smaller than the reference potential Vref that is output in the cyclic mode and the hybrid mode. Therefore, in the second-order ΔΣ mode, it is possible to implement the operational stability of the integrator 11. The quantizer 12 can perform appropriate quantization.

The capacitors Cs1p, Csd1p, Cs1m, and Csd1m, and the capacitors Csd1p, Ccd1p, Ccd2p, Csd1m, Ccd1m, and Ccd2m may be configured by combining unit capacitors of unit capacitance, each having the same area, in an array. Therefore, it is possible to easily obtain a match and reduce mismatches. Therefore, it is possible to reduce the gain error of the switched capacitor amplifier that constitutes the first-order integrator 11a, and implement high linearity and low gain error.

The control circuit 10 switches the operation mode by switching the integrator output changeover switch 11c, so there is no need to use an extra capacitor. Therefore, the A/D conversion device 101 that implements a plurality of operation modes can be configured as compact as possible.

According to the present embodiment, it is possible to implement the low-speed, high-precision second-order ΔΣ mode, the high-speed, low-precision cyclic mode, and the medium-speed, medium-precision hybrid mode using the same hardware. This can be configured at a lower cost than if these operation modes were implemented separately. Because the hybrid mode is a combination of the first-order ΔΣ mode and the cyclic mode, there is no need to prepare hardware for each operation mode, and it can be implemented at low cost.

Furthermore, when a high voltage of about 100 V is input as the analog input signal Vin, as in the battery monitoring integrated circuit device 1 described in the present embodiment, capacitors Cs1p, Cs1m, Csd1p, and Csd1m, which serve as sampling capacitances, have a high withstand voltage capacity. In this case, by configuring the A/D conversion device 101 in the present embodiment, it is possible to provide the configuration capable of withstanding high-voltage input, and by switching the operation mode, it is possible to switch the precision and speed. Therefore, it is possible to implement the A/D conversion device 101 that meets the requirements.

For example, there is a case where the plurality of battery cells 4a, 4b, . . . , 4c are monitored and the cell voltage of each battery cell 4a, 4b, . . . , 4c is detected with high precision, and a case of scanning and diagnosing all of the battery cells 4a . . . 4c at high speed. In these cases, when the required precision and speed differ greatly, the single A/D conversion device 101 can meet these requirements by switching the operation modes.

### SECOND EMBODIMENT

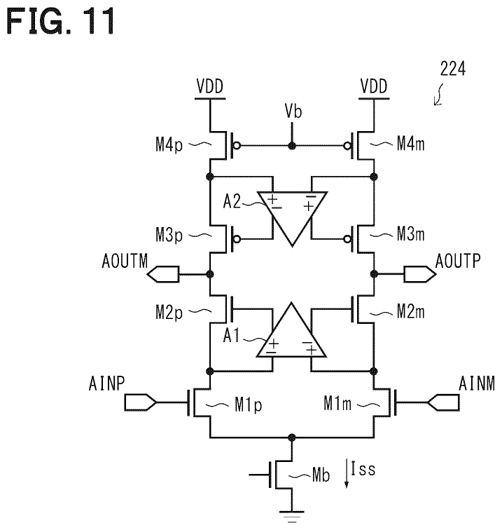

A second embodiment will be described with reference to FIG. 11. It is desirable to use a telescopic amplifier 224 with a gain boost amplifier as shown in FIG. 11 for the operational amplifiers 24 and 24b that constitute the switched capacitor amplifier.

The telescopic amplifier 224 is configured by combining an input MOS transistor pair M1p-M1m that receives a differential input signal AINP-AINM, MOS transistor pairs M2p-M2m, M3p-M3m, and M4p-M4m that are telescopically cascode-connected to the input MOS transistor pair M1p-M1m, fully differential operational amplifiers A1 and A2, and a MOS transistor Mb that serves as a current source. Although not shown in FIG. 11, the MOS transistor Mb constitutes a current mirror circuit and is configured to pass a constant current Iss.

The MOS transistor pairs M1p-M1m and M2p-M2m are each composed of an n-channel MOSFET, and the MOS transistor pairs M3p-M3m and M4p-M4m are each composed of a p-channel MOSFET.

The fully differential operational amplifier A1 is provided for gain boosting, and its differential input terminals are connected respectively to the common connection point of the drain of MOS transistor M1p and the source of M2p, and to the common connection point of the drain of MOS transistor M1m and the source of M2m. The differential output terminals of the fully differential operational amplifier A1 are connected to the gates of the MOS transistors M2p and M2m, respectively.

The fully differential operational amplifier A2 is provided for gain boosting, and its differential input terminals are connected respectively to the common connection point of the drain of MOS transistor M4p and the source of M3p, and to the common connection point of the drain of MOS transistor M4m and the source of M3m. The differential output terminals of the fully differential operational amplifier A2 are connected to the gates of the MOS transistors M3p and M3m, respectively. The MOS transistors M2p and M3p, and M2m and M3m are commonly connected to output terminals that output differential output signals AOUTM-AOUTP.

The A/D conversion device 101 uses the operational amplifiers 24 and 24b for switched capacitor amplifiers. The switched capacitor amplifier has no current load because it is configured by combining switches and capacitors (reference numerals omitted). Therefore, the operational amplifiers 24 and 24b are configured using the telescopic amplifier 224 with gain-boost amplifiers as shown in FIG. 11. Thereby, it is possible to implement the switched capacitor amplifier with low power consumption and high precision.

However, when it is configured with a simple one-stage amplifier, a current load is generated. Therefore, it is more likely that nonlinear errors will occur. When a two-stage amplifier is used to increase the gain, the current consumption increases. Like the telescopic amplifier 224, by adding fully differential operational amplifiers A1 and A2 for gain boost to a single-stage amplifier, it is possible to configure it with low power consumption and high precision.

It should be noted that the input/output common voltage range (common range) of the telescopic amplifier 224 tends to be narrow. However, as described in the first embodiment, the potential generation circuit 14 changes and applies the reference potential Vref, which is the threshold value of quantization, to the quantizer 12. Therefore, even when the input range of the quantizer 12 is limited, the reference potential Vref can be adjusted in order to match the input range. Therefore, it is possible to improve the degree of freedom of the input/output voltage range of the operational amplifier 24b. Even when the telescopic amplifier 224 is used for the operational amplifier 24b, the quantizer 12 can perform accurate quantization to an appropriate level.

### THIRD EMBODIMENT

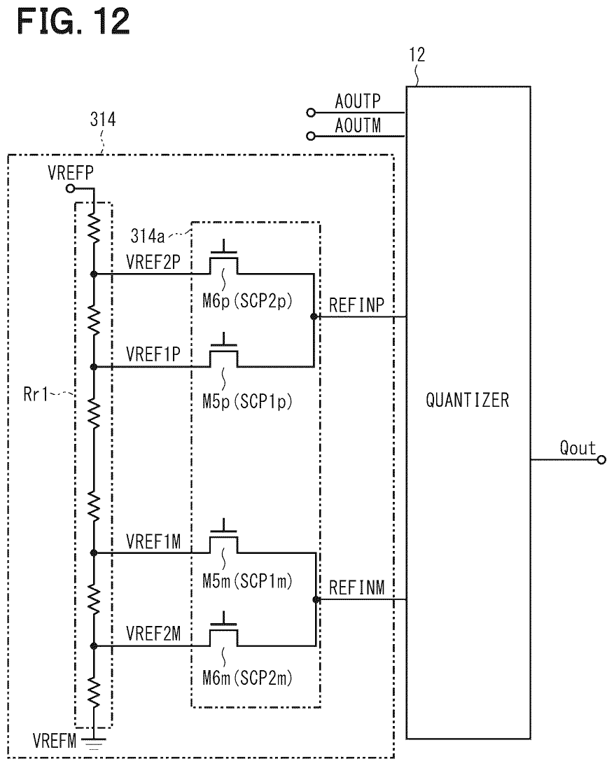

A third embodiment will be described with reference to FIG. 12. In the third embodiment, the configuration example of the potential generation circuit 14 described in the first embodiment will be described as a potential generation circuit 314. The potential generation circuit 314 shown in FIG. 12 includes switches SCP1p, SCP2p, SCP1m, and SCP2m as a reference potential switch 314a, and generates the plurality of reference potentials Vref for a comparison target of the quantizer 12. In FIG. 12, the plurality of reference potentials Vref are separately shown as a reference potential REFINP having a relatively high potential and a reference potential REFINM having a relatively low potential.

As shown in FIG. 12, the potential generation circuit 314 is configured by combining a resistor ladder Rr1, MOSFETs M5p, M6p, M5m, and M6m. The MOSFETs M5p, M6p, M5m, and M6m are all configured as n-channel types. The resistor ladder Rr1 is configured by connecting a plurality of voltage dividing resistors between an application node of the highest reference potential VREFP and an application node of the lowest reference potential VREFM. Reference potentials VREF2P, VREF1P, VREF1M, and VREF2M are generated by divided voltages of a plurality of voltage dividing resistors. It should be noted that there is a relationship of VREF2P>VREF1P>VREF1M>VREF2M.

The switch SCP2p is configured by the MOSFET M6p. The divided voltage VREF2P of the resistor ladder Rr1 is input to one of the drain and source of the MOSFET M6p, and the other of the drain and source is connected to the input terminal of the reference potential REFINP of the quantizer 12. The switch SCP1p is configured by the MOSFET M5p. The divided voltage VREF1P of the resistor ladder Rr1 is input to one of the drain and source of the MOSFET M5p, and the other of the drain and source is connected to the input terminal of the reference potential REFINP of the quantizer 12.

The control circuit 10 can input one of the reference potentials VREF2P and VREF1P to the quantizer 12 as the reference potential REFINP by turning on one of the MOSFETs M5p and M6p.

The switch SCP1m is configured by the MOSFET M5m. The divided voltage VREF1M of the resistor ladder Rr1 is input to one of the drain and source of the MOSFET M5m, and the other of the drain and source is connected to the input terminal of the reference potential REFINM of the quantizer 12. The switch SCP2m is configured by the MOSFET M6m. The divided voltage VREF2M of the resistor ladder Rr1 is input to one of the drain and source of the MOSFET M6m, and the other of the drain and source is connected to the input terminal of the reference potential REFINM of the quantizer 12.

The control circuit 10 can input one of the reference potentials VREF1M and VREF2M to the quantizer 12 as the reference potential REFINM by turning on one of the MOSFETs M5m and M6m. Thereby, the potential generation circuit 14 can input the reference potential Vref that satisfies the relationship of REFINP>REFINM to the quantizer 12.

According to the present embodiment, by configuring only one resistor ladder Rr1, the plurality of reference potentials Vref (REFINP, REPINM) can be configured with low power consumption and in a small size. The larger the area of the resistor ladder Rr1, the smaller the mismatch between the voltage dividing resistors can be. Therefore, by adopting the resistor ladder Rr1, it is possible to reduce the size. By increasing the installation area of each resistor of the resistor ladder Rr1 due to the reduction of the size, it is possible to reduce the influence of mismatch.

When the control circuit 10 switches the output of the voltage dividing resistors by switching the on-off states of the MOS transistors M5p, M6p, M5m, and M6m, the reference potential Vref fluctuates at the time of switching. Therefore, it is desirable to temporarily stop the AD conversion process when switching the operation mode of the A/D conversion device 101 and switch the reference potential Vref during this stop. By switching the reference potential Vref while the AD conversion process is temporarily stopped, the precision of the AD conversion is not adversely affected.

### FOURTH EMBODIMENT

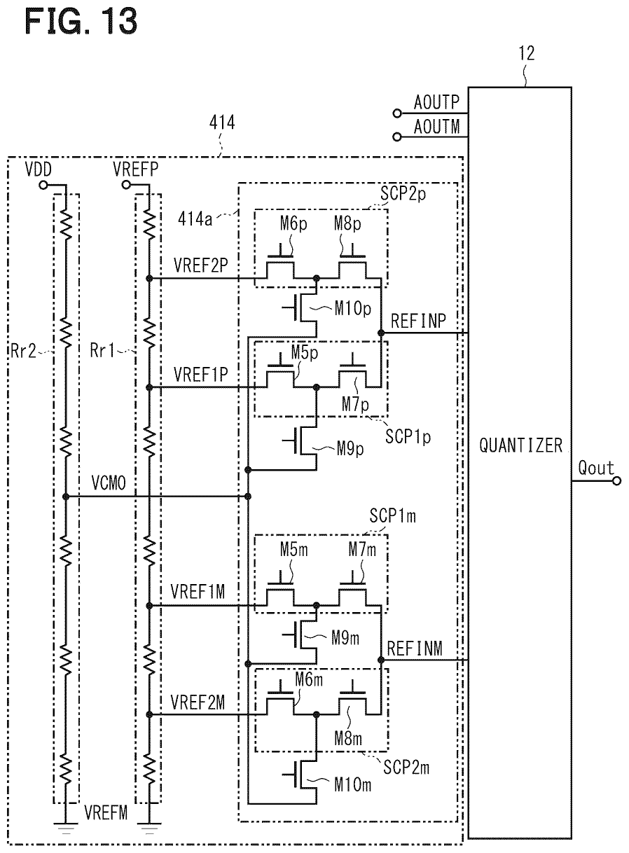

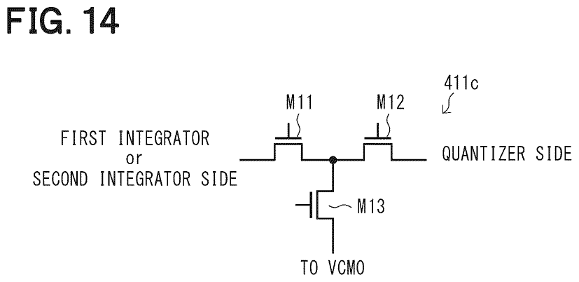

The fourth embodiment will be described with reference to FIGS. 13 and 14. In the fourth embodiment, the configuration example of the potential generation circuit 14 in the first embodiment will be described as a potential generation circuit 414, but the same components as in the third embodiment will be assigned the same reference numerals and description thereof will be omitted. Further, in the present embodiment, the configuration example of the integrator output changeover switch 11c will be described as an integrator output changeover switch 411c.

The potential generation circuit 414 includes a resistor ladder Rr2 in addition to the resistor ladder Rr1, and also includes switches SCP1p, SCP2p, SCP1m, and SCP2m as a reference potential switch 414a, and generates the plurality of reference potentials Vref for the comparison target of the quantizer 12. In FIG. 13, the plurality of reference potentials Vref are separately shown as the reference potential REFINP having a relatively high potential and the reference potential REFINM having a relatively low potential.

The resistor ladder Rr2 is configured by connecting a plurality of voltage dividing resistors between the application node of the power supply voltage VDD and the application node of the lowest reference potential VREFM, and generates a common potential VCM0 by divided voltages of the plurality of voltage dividing resistors.

The switch SCP1p of the reference potential switch 414a includes a MOSFET M7p in addition to a MOSFET M5p. The switch SCP1p is configured by connecting the drains/sources of two MOSFETs M5p and M7p in series. When the switch SCP1p is on, the control circuit 10 controls the MOSFETs M5p and M7p to be turned on and controls the MOSFET M9p to be turned off. Furthermore, when the switch SCP1p is turned off, the control circuit 10 controls the MOSFETs M5p and M7p to be turned off and controls the MOSFET M9p to be turned on. Thereby, the intermediate potential is connected to the common potential VCM0 via the MOSFET M9p.

The switch SCP2p of the reference potential switch 414a includes a MOSFET M8p in addition to the MOSFET M6p. The switch SCP2p is configured by connecting the drains/sources of two MOSFETs M6p and M8p in series. When the control circuit 10 controls the switch SCP2p to be turned on, it controls the MOSFETs M6p and M8p to be turned on and controls a MOSFET M10p to be turned off. Furthermore, when the control circuit 10 controls the switch SCP2p to be turned off, it controls the MOSFETs M6p and M8p to be turned off and controls the MOSFET M10p to be turned on. Thereby, the intermediate potential is connected to the common potential VCM0 via the MOSFET M10p.

The switch SCP1m of the reference potential switch 414a includes a MOSFET M7m in addition to the MOSFET M5m. The switch SCP1m is configured by connecting the drains/sources of two MOSFETs M5m and M7m in series. When the control circuit 10 controls the switch SCP1m to be turned on, it controls the MOSFETs M5m and M7m to be turned on and controls the MOSFET M9m to be turned off. Furthermore, when the control circuit 10 controls the switch SCP1m to be turned off, it controls the MOSFETs M5m and M7m to be turned off and controls the MOSFET M9m to be turned on. Thereby, the intermediate potential is connected to the common potential VCM0 via the MOSFET M9m.

The switch SCP2m of the reference potential switch 414a includes a MOSFET M8m in addition to the MOSFET M6m. The switch SCP2m is configured by connecting the drains/sources of two MOSFETs M6m and M8m in series. When the control circuit 10 controls the switch SCP2m to be turned on, it controls the MOSFETs M6m and M8m to be turned on and also controls the MOSFET M10m to be turned off. Furthermore, when the control circuit 10 controls the switch SCP2m to be turned off, it controls the MOSFETs M6m and M8m to be turned off and controls the MOSFET M10m to be turned on. Thereby, the intermediate potential is connected to the common potential VCM0 via the MOSFET M10m.

Furthermore, as shown in FIG. 14, each of the switches SCMP1p, SCMP2p, SCMP1m, and SCMP2m of the integrator output changeover switch 411c may be configured by combining MOSFETs M11, M12, and M13. The switches SCMP1p, SCMP2p, SCMP1m, and SCMP2m of the integrator output changeover switch 411c are configured such that the drains/sources of two MOSFETs M11 and M12 are connected in series.

When the control circuit 10 controls the switches SCMP1p, SCMP2p, SCMP1m, and SCMP2m to be turned on, it controls the MOSFETs M11 and M12 to be turned on and controls the MOSFET M13 to be turned off. Furthermore, when the control circuit 10 controls each switch SCMP1p, SCMP2p, SCMP1m, and SCMP2m to be turned off, it controls MOSFET M11 and M12 to be turned off and controls MOSFET M13 to be turned on. Thereby, the intermediate potential is connected to the common potential VCM0 via MOSFET M13.

When the reference potentials VREP1P, VREP2P, VREP1M, and VREP2M or the output of the operational amplifier 24b are close to the power supply potential VDD or the lowest reference potential VREFM (for example, ground potential), current may leak from the reference potential switches SCP1p, SCP2p, SCP1m, and SCP2m and the integrator output changeover switches SCMP1p, SCMP2p, SCMP1m, and SCMP2m, and the AD conversion errors may become large.

As shown in FIG. 13, by configuring the potential generation circuit 414, intermediate potentials are set between the MOSFETs M5p and M7p, M5m and M7m, M6p and M8p, and M6m and M8m. In particular, a gate-source voltage Vgs of MOSFET M5p or M6p, M5m or M6m can be made negative, and the substrate bias effect can be achieved. Thereby, it is possible to reduce leakage and AD conversion errors, and implement the high precision.

As shown in FIG. 14, by configuring the integrator output changeover switch 411c, the potential between MOSFETs M11 and M12 becomes intermediate. In particular, the gate-source voltage Vgs of the MOSFET M11 can be made negative, and the substrate bias effect can be achieved. Thereby, it is possible to reduce leakage and AD conversion errors, and implement the higher precision.

### OTHER EMBODIMENTS

The present disclosure is not limited to the embodiments described above, but can be implemented by various modifications, and can be applied to various embodiments without departing from the spirit of the present disclosure. For example, the following modifications or extensions can be performed. Each component is conceptual and is not limited to the above-described embodiments.

The D/A converter output VR is not limited to three levels, but may be set appropriately according to the number of levels of the quantized value in the quantizer 12. The number of reference potentials Vref of the potential generation circuit 14 may be set in accordance with the number of levels of the quantized value of the quantizer 12. The number of levels of the D/A converter outputs VR of the DACs 25, 26, and 27 of the capacitor switching circuits 20, 21, and 22 may be changed in accordance with the number of levels of the quantized value.

The capacitance values of capacitors Cs1p, Csd1p, Cs2p, Csd2p, Ccc1p, Ccd1p, Ccc2p, Ccd2p, Cf11p, Cf21p, Cs1m, Csd1m, Cs2m, Csd2m, Ccc1m, Ccd1m, Ccc2m, Ccd2m, Cf11m, and Cf21m may be scaled appropriately to correspond to the input/output range of each operational amplifier 24, 24b.

The A/D conversion device and the battery monitoring integrated circuit device described in the present disclosure may be implemented by a special purpose computer which is configured with a memory and a processor programmed to execute one or more particular functions embodied in computer programs of the memory. Alternatively, the A/D conversion device and the battery monitoring integrated circuit device described in the present disclosure may be implemented by a dedicated computer configured as a processor with one or more dedicated hardware logic circuits. Alternatively, the A/D conversion device and the battery monitoring integrated circuit device described in the present disclosure may be implemented by one or more dedicated computer, which is configured as a combination of a processor and a memory, which are programmed to perform one or more functions, and a processor which is configured with one or more hardware logic circuits. Additionally, the computer program may be stored on a computer-readable non-transitory tangible storage medium as instructions executed by a computer.

Although the present disclosure has been described in accordance with the embodiments, it is understood that the present disclosure is not limited such embodiments or structures described in the embodiments. The present disclosure includes various modification examples and equivalents thereof. Furthermore, various combinations and aspects, and other combination and aspect including only one element, more than one element or less than one element, are also within the sprit and scope of the present disclosure.

What is claimed is:

1. An analog-to-digital (A/D) conversion device comprising:
an integrator to which an input signal and an output of a digital-to-analog converter (DAC) are input;
a quantizer to which a reference potential is applied and to which the output of the integrator is input;
the DAC that performs digital-to-analog conversion of the output of the quantizer;
a control circuit that performs switching between two or more operation modes including a second-order ΔΣ mode and a cyclic mode; and
a potential generation circuit that switches the reference potential to be applied to the quantizer depending on the two or more operation modes.

2. The A/D conversion device according to claim 1, wherein
the integrator includes:
a first-order integrator that receives the input signal and the output of the DAC;
a second-order integrator that receives an output of the first-order integrator and the output of the DAC; and
an integrator output changeover switch that selectively switches the input to the quantizer between the output of the first-order integrator and the output of the second-order integrator.

3. The A/D conversion device according to claim 2, wherein
an operation in the cyclic mode is performed by using the first-order integrator, and cuts an operating current of the second-order integrator.

4. The A/D conversion device according to claim 3, wherein
the DAC includes a DAC capacitance,
the integrator includes a switch and a switched capacitor amplifier configured by combining a sampling capacitor that inputs the input signal and the DAC capacitance of the DAC with an identical capacitance value, and
a gain of the switched capacitor amplifier is switched by switching the switch.

5. The A/D conversion device according to claim 4, wherein
a telescopic amplifier with a gain boost amplifier is used as the switched capacitor amplifier.

6. The A/D conversion device according to claim 4, wherein
the control circuit switches between three or more modes, including:
a second-order ΔΣ mode in which the output of the second-order integrator is used by switching with an output changeover switch;
a cyclic mode in which a cyclic operation is performed; and
a hybrid mode in which an A/D conversion is performed by switching, via the output changeover switch, between a first-order ΔΣ operation using the output of the first-order integrator and the cyclic operation during conversion.

7. The A/D conversion device according to claim 6, wherein
in the hybrid mode, the A/D conversion starts with the first-order ΔΣ operation, and during the A/D conversion, a switch on-off state is changed to perform the cyclic operation, and an A/D conversion result of the first-order ΔΣ operation and an A/D conversion result of the cyclic operation are combined to output an A/D conversion result of the hybrid mode.

8. The A/D conversion device according to claim 4, wherein
the potential generation circuit is configured by combining a resistor ladder and a reference potential changeover switch, and configured to change the reference potential.

9. The A/D conversion device according to claim 8, wherein
the control circuit switches the reference potential changeover switch in synchronization with switching of the two or more operation modes of the A/D conversion.

10. The A/D conversion device according to claim 9, wherein
the reference potential changeover switch is configured to have two metal-oxide-semiconductor field-effect transistors (MOSFETs) of a first MOSFET and a second MOSFET, connected in series, and
when the reference potential changeover switch is turned off, an intermediate potential between the first MOSFET and the second MOSFET is connected to a common potential via a third MOSFET.

11. A battery monitoring integrated circuit device comprising
an analog-to-digital conversion device including:
an integrator to which an input signal and an output of a digital-to-analog converter (DAC) are input;
a quantizer to which a reference potential is applied and to which the output of the integrator is input;
the DAC that includes a DAC capacitance and performs digital-to-analog conversion of an output of the quantizer;
a control circuit that performs switching between two or more operation modes including a second-order ΔΣ mode and a cyclic mode; and
a potential generation circuit that switches the reference potential to be applied to the quantizer depending on the two or more operation modes.
